(19) United States
(12) Patent Application Publication
(10) Pub. No.: US 2024/0030185 A1
(43) Pub. Date: Jan. 25, 2024

(54) SEMICONDUCTOR PACKAGE

(71) Applicant: Samsung Electronics Co., Ltd., Suwon-si (KR)

(72) Inventors: JU-YOUN CHOI, Suwon-si (KR); Seunggeol RYU, Suwon-si (KR); YUN SEOK CHOI, Suwon-si (KR)

(21) Appl. No.: 18/112,107

(22) Filed: Feb. 21, 2023

(30) Foreign Application Priority Data
Jul. 19, 2022 (KR) 10-2022-0089105

(51) Int. Cl. H01L 25/065; H01L 23/498; H01L 23/31; H01L 23/48; H01L 23/538

(52) U.S. Cl. CPC H01L 25/0652; H01L 23/49816; H01L 23/3128; H01L 23/481; H01L 23/5389; H01L 23/5386

(57) ABSTRACT

A semiconductor package comprising a main semiconductor chip having a first thickness, at least one semiconductor device on one side of the main semiconductor chip and having a second thickness less than the first thickness, a first molding layer that covers the main semiconductor chip and the semiconductor device so as to expose a top surface of the semiconductor device and to expose a top surface and a portion of a lateral surface of the main semiconductor chip, a first redistribution substrate below the first molding layer, a second redistribution substrate on the first molding layer, and a mold via that penetrates the first molding layer and connects the first redistribution substrate to the second redistribution substrate.

### CROSS-REFERENCE TO RELATED APPLICATION

This U.S. nonprovisional application claims priority under 35 U.S.C § 119 to Korean Patent Application No. 10-2022-0089105 filed on Jul. 19, 2022 in the Korean Intellectual Property Office, the disclosure of which is hereby incorporated by reference in its entirety.

### BACKGROUND

Aspects of the present inventive concept relate to a semiconductor device, and more particularly, to a semiconductor device including a redistribution substrate.

A semiconductor package is provided to implement an integrated circuit chip to qualify for use in electronic products. For example, a semiconductor package is configured such that a semiconductor chip is mounted on a printed circuit board (PCB) and bonding wires or bumps are used to electrically connect the semiconductor chip to the printed circuit board. With the recent developments in the electronic industry, the semiconductor package is variously developed to reach the goal of compact size, small weight, and/or low manufacturing cost. In addition, many kinds of semiconductor packages are developed as a result of the expansion of their application field such as high-capacity mass storage devices.

### SUMMARY

Some embodiments of the present inventive concepts provide a semiconductor package with improved thermal properties.

Aspects of the present inventive concept is not limited to the mentioned above, and other aspects which have not been mentioned above will be clearly understood to those skilled in the art from the following description.

According to some embodiments of the present inventive concepts, a semiconductor package may comprise: a main semiconductor chip having a first thickness; at least one semiconductor device on one side of the main semiconductor chip and having a second thickness less than the first thickness; a first molding layer that covers the main semiconductor chip and the semiconductor device so as to expose a top surface of the semiconductor device and to expose a top surface and a portion of a lateral surface of the main semiconductor chip; a first redistribution substrate below the first molding layer; a second redistribution substrate on the first molding layer; and a mold via that penetrates the first molding layer and connects the first redistribution substrate to the second redistribution substrate.

According to some embodiments of the present inventive concepts, a semiconductor package may comprise: a first redistribution substrate; a main semiconductor chip on the first redistribution substrate; a second redistribution substrate on the first redistribution substrate, a top surface of the second redistribution substrate being at a level lower than a level of the main semiconductor chip; a first molding layer between the first redistribution substrate and the second redistribution substrate; and a second molding layer that covers the second redistribution substrate and exposes a top surface of the main semiconductor chip.

According to some embodiments of the present inventive concepts, a semiconductor package may comprise: a main semiconductor chip; a first redistribution substrate below the main semiconductor chip; external connection terminals bonded to a bottom surface of the first redistribution substrate; first redistribution patterns in the first redistribution substrate; a second redistribution substrate that extends parallel to the first redistribution substrate and extends in an outward direction from a lateral surface of the main semiconductor chip; second redistribution patterns in the second redistribution substrate; at least one semiconductor device between the first redistribution substrate and the second redistribution substrate; a first molding layer between the first redistribution substrate and the second redistribution substrate, the first molding layer covering a portion of the lateral surface of the main semiconductor chip; and a second molding layer that covers the second redistribution substrate and another portion of the lateral surface of the main semiconductor chip, the second molding layer exposing a top surface of the main semiconductor chip. Each of the first redistribution patterns may include a first line part and a first via part on the first line part. Each of the second redistribution patterns may include a second line part and a second via part on the second line part. One of the first and second redistribution patterns may transmit a power. Another of the first and second redistribution patterns may transmit a signal. The main semiconductor chip may have a first thickness. The at least one semiconductor device may have a second thickness. The first thickness may be about 2 to 5 times the second thickness.

### BRIEF DESCRIPTION OF THE DRAWINGS

FIG. 1 illustrates a plan view showing a semiconductor package according to some embodiments of the present inventive concepts.

FIG. 2 illustrates a cross-sectional view taken along line I-I′ of FIG. 1, showing a semiconductor package according to some embodiments of the present inventive concepts.

FIG. 3 illustrates an enlarged view showing section A of FIG. 2.

FIGS. 4 to 15 illustrate cross-sectional views showing a method of fabricating a semiconductor package according to some embodiments of the present inventive concepts.

FIG. 16 illustrates a cross-sectional view showing a semiconductor package according to some embodiments of the present inventive concepts.

FIG. 17 illustrates a cross-sectional view showing a semiconductor package according to some embodiments of the present inventive concepts.

### DETAIL PARTED DESCRIPTION OF EMBODIMENTS

Some embodiments of the present inventive concepts will now be described in detail with reference to the accompanying drawings to aid in clearly explaining aspects of the present inventive concepts.

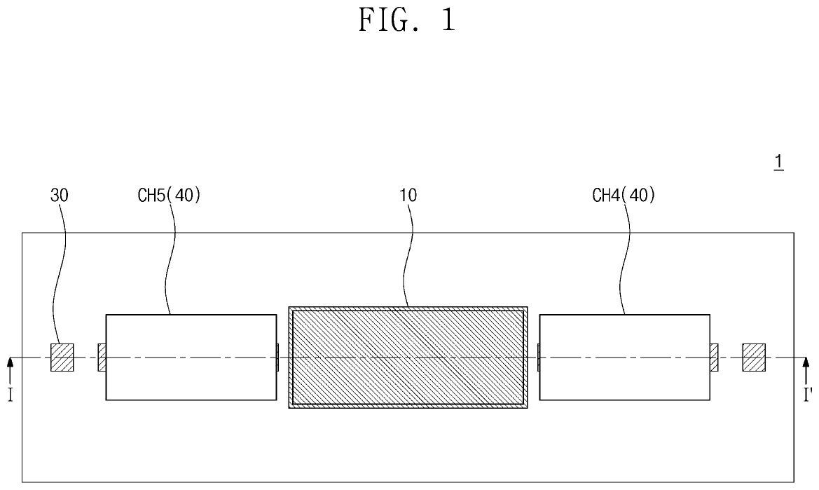

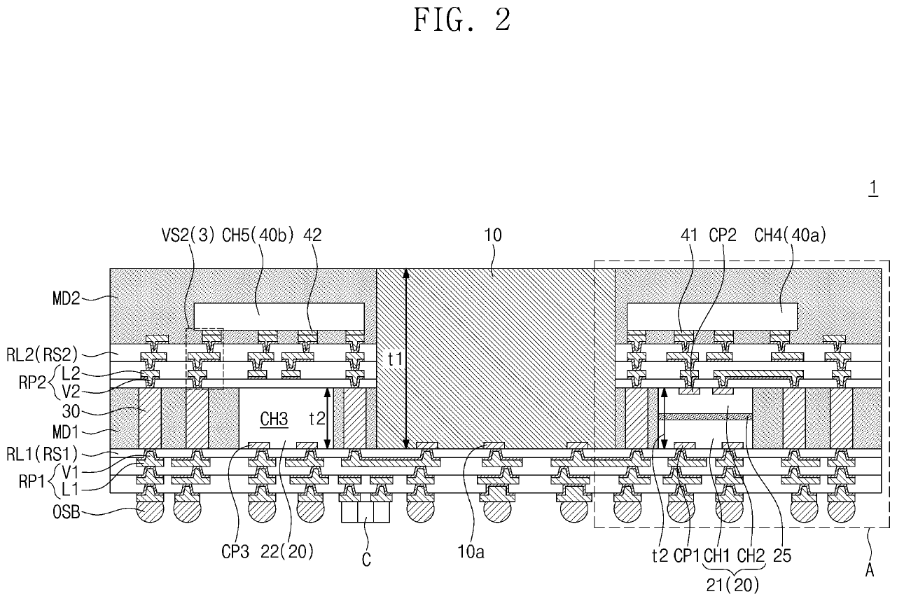

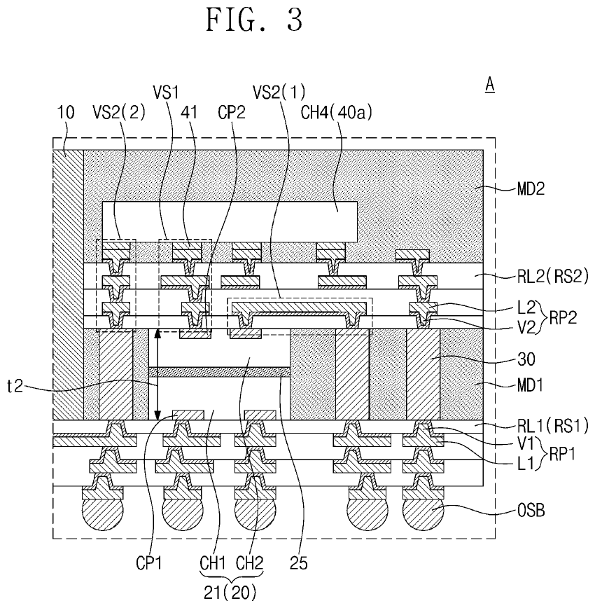

FIG. 1 illustrates a plan view showing a semiconductor package according to some embodiments of the present inventive concepts. FIG. 2 illustrates a cross-sectional view taken along line I-I′ of FIG. 1, showing a semiconductor package according to some embodiments of the present inventive concepts. FIG. 3 illustrates an enlarged view showing section A of FIG. 2.

Referring to FIGS. 1, 2, and 3, a semiconductor package 1 may be shaped like a chip-first type fan-out wafer level package (FOWLP). The semiconductor package 1 may include a main semiconductor chip 10, a semiconductor device 20, a first molding layer MD1, a first redistribution substrate RS1, a second redistribution substrate RS2, and a mold via 30. The first redistribution substrate RS1 and the second redistribution substrate RS2 may each extend in a first direction (e.g., X-direction) and a second direction (e.g., Y-direction) perpendicular to the first direction.

The main semiconductor chip 10 may be disposed on the first redistribution substrate RS1. The main semiconductor chip 10 may have a first thickness t1. The first thickness t1 may be measured in a third direction (e.g., Z-direction) perpendicular to the first direction and the second direction. The first thickness t1 may be the same as a height between bottom and top surfaces of the main semiconductor chip 10.

The main semiconductor chip 10 may be in contact with a top surface of the first redistribution substrate RS1. The main semiconductor chip 10 may include a logic chip, a buffer chip, or a system-on-chip (SOC). For example, the main semiconductor chip 10 may be an application specific integrated circuit (ASIC) chip or an application processor (AP) chip. The ASIC chip may include an application specific integrated circuit (ASIC). The main semiconductor chip 10 may include a central processing unit (CPU) or a graphic processing unit (GPU).

At least one semiconductor device 20 may be disposed on one side of the main semiconductor chip 10. The at least one semiconductor device 20 may include one semiconductor chip, or two or more semiconductor chips that are stacked on each other. The at least one semiconductor device 20 may have a second thickness t2 less than the first thickness t1. In this case, the first thickness t1 may be about 2 to 5 times the second thickness t2.

For example, the at least one semiconductor device 20 may have a top surface located at a lower level (e.g., in the Z-direction) than that of the top surface of the main semiconductor chip 10. In this description, the second thickness t2 may be the same as a distance between the first redistribution substrate RS1 and the second redistribution substrate RS2 that are discussed below.

The semiconductor device 20 may include a first semiconductor device 21 and a second semiconductor device 22. The first semiconductor device 21 and the second semiconductor device 22 may be disposed on opposite sides of the main semiconductor chip 10 on the first redistribution substrate RS1. Although the first semiconductor device 21 and the second semiconductor device 22 are illustrated to have the same second thickness t2, the first semiconductor device 21 and the second semiconductor device 22 may have different thicknesses from each other, and may each have a thickness that is variously changed within a range less than the thickness of the main semiconductor chip 10.

When the second thickness t2 is given to at least one selected from the first semiconductor device 21 and the second semiconductor device 22, the at least one selected from the first semiconductor device 21 and the second semiconductor device 22 may have a bottom surface in contact with the first redistribution substrate RS1 and a top surface in contact with the second redistribution substrate RS2.

The first semiconductor device 21 may include two semiconductor chips, for example, a first semiconductor chip CH1 and a second semiconductor chip CH2. The second semiconductor device 22 may include one semiconductor chip, fore example, a third semiconductor chip CH3. Alternatively, the first semiconductor device 21 may include one semiconductor chip, and the second semiconductor device 22 may include two semiconductor chips.

The first semiconductor chip CH1 and the second semiconductor chip CH2 may be stacked on each other. The second semiconductor chip CH2 may be positioned on the first semiconductor chip CH1.

The first redistribution substrate RS1 may include a first redistribution dielectric layer RL1 and a first redistribution pattern RP1. The first redistribution dielectric layer RL1 may be a single or multi-stacked layer. In some embodiments, no distinct interface may be provided between two adjacent ones of the first redistribution dielectric layers RL1.

The number of stacked first redistribution dielectric layers RL1 is not be limited to that shown, but may be variously changed. The first redistribution dielectric layer RL1 may include a dielectric polymer or a photo-imageable dielectric (PID). For example, the photo-imageable dielectric may include at least one selected from photosensitive polyimide, polybenzoxazole (PBO), phenolic polymers, and benzocyclobutene polymers.

The first redistribution pattern RP1 may be disposed in the first redistribution dielectric layer RL1. The first redistribution pattern RP1 may be provided in plural. As shown in FIG. 2, each of the first redistribution patterns RP1 may include a first line part L1 and a first via part V1. In this description, a via part of a certain component may be a segment for vertical connection (e.g., in the third direction), and a line part of a certain component may be a segment for horizontal connection (e.g., in the first and/or second directions). In this case, the line part may have a width (e.g., in the first direction) greater than that of the via part. The first line part L1 may have a major axis that extends in a direction parallel (e.g., the first direction) to the top surface of the first redistribution substrate RS1. The first line part L1 may have a width (e.g., in the first direction) greater than that of the first via part V1. The first via part V1 may be disposed on the first line part L1. The first via part V1 may have a shape that protrudes toward the top surface of the first redistribution substrate RS1. An uppermost portion of the first via part V1 may have a width (e.g., in the first direction) less than that of a lowermost portion of the first via part V1. The first redistribution pattern RP1 may include a conductive material, for example, at least one selected from copper (Cu), tungsten (W), and titanium (Ti).

Although the first redistribution substrate RS1 is illustrated to include three first redistribution dielectric layers RL1, the first redistribution substrate RS1 may include two or at least four first redistribution dielectric layers RL1 each having the first redistribution pattern RP1 therein.

External connection terminals OSB may be bonded to bottom surfaces of lowermost ones of the first redistribution patterns RP1. The external connection terminals OSB may be in contact with bottom surfaces of the first line parts L1 of the lowermost first redistribution patterns RP1. The external connection terminals OSB may include a conductive material, for example, at least one selected from nickel (Ni) and gold (Au).

The lowermost first redistribution patterns RP1 may have at least one first redistribution pattern RP1 to which the external connection terminal OSB is not bonded, and a capacitor C may be bonded to a bottom surface of the at least one first redistribution pattern RP1. The capacitor C may serve as a decoupling capacitor for voltage stabilization of at least one semiconductor chip. The capacitor C may include a multi-layer ceramic capacitor (MLCC) or a silicon capacitor. The capacitor C may have capacitance of about hundreds of nF. The multi-layer ceramic capacitor may include, for example, a low inductance chip capacitor (LICC) having a vertically laminated three-terminal structure, a multi-terminal type low-ESL (equivalent series inductance) MLCC, a multi-layer ceramic capacitor (MLCC) whose electrodes are present only on a lower portion thereof.

The first redistribution substrate RS1 may be provided thereon with the first molding layer MD1 that covers the main semiconductor chip 10 and the semiconductor device 20. In this case, the first molding layer MD1 may cover the main semiconductor chip 10 and the at least one semiconductor device 20 while exposing (i.e., not cover) the top surface and a portion of a lateral surface of the main semiconductor chip 10 and the top surface of the at least one semiconductor device 20. As the main semiconductor chip 10 has a thickness greater than that of the semiconductor device 20 as discussed above, a portion of the lateral surface of the main semiconductor chip 10 may be exposed (i.e., not covered by the first molding layer MD1) when the first molding layer MD1 completely covers a lateral surface of the semiconductor device 20. The first molding layer MD1 may include a dielectric polymer, such as an epoxy molding compound (EMC).

The first molding layer MD1 may be interposed between the first redistribution substrate RS1 and the second redistribution substrate RS2 which will be discussed below. The first molding layer MD1 may fill a space between the top surface of the first redistribution substrate RS1 and a bottom surface of the second redistribution substrate RS2.

The second redistribution substrate RS2 may be provided on the first semiconductor device 21 and the second semiconductor device 22 so as to cover the top surface of each of the first semiconductor device 21 and the second semiconductor device 22. In this configuration, the second redistribution substrate RS2 may contact the lateral surface of the main semiconductor chip 10 to have a shape that extends in an outward direction from the lateral surface of the main semiconductor chip 10. Therefore, the first molding layer MD1 may surround a portion of the lateral surface of the main semiconductor chip 10.

The second redistribution substrate RS2 may include a second redistribution dielectric layer RL2 and a second redistribution pattern RP2. The second redistribution dielectric layer RL2 may be a single or multi-stacked layer. In some embodiments, no distinct interface may be provided between two adjacent ones of the second redistribution layers RL2.

The number of stacked second redistribution dielectric layers RL2 is not be limited to that shown, but may be variously changed. The second redistribution dielectric layer RL2 may include a dielectric polymer or a photo-imageable dielectric (PID). For example, the photo-imageable dielectric may include at least one selected from photosensitive polyimide, polybenzoxazole (PBO), phenolic polymers, and benzocyclobutene polymers.

The second redistribution pattern RP2 may be disposed in the second redistribution dielectric layer RL2. The second redistribution pattern RP2 may be provided in plural. As shown in FIG. 2, each of the second redistribution patterns RP2 may include a second line part L2 and a second via part V2.

In this description, a via part of a certain component may be a segment for vertical connection e.g., in the third direction), and a line part of a certain component may be a segment for horizontal connection (e.g., in the first and/or second directions). In this case, the line part may have a width (e.g., in the first direction) greater than that of the via part. The second line part L2 may have a major axis that extends in a direction parallel (e.g., the first direction) to a top surface of the second redistribution substrate RS2. The second line part L2 may have a width (e.g., in the first direction) greater than that of the second via part V2. The second via part V2 may be disposed below the second line part L2. The second via part V2 may have a shape that protrudes toward the bottom surface of the second redistribution substrate RS2. A lowermost portion of the second via part V2 may have a width (e.g., in the first direction) less than that of an uppermost portion of the second via part V2. The second redistribution pattern RP2 may include a conductive material, for example, at least one selected from copper (Cu), tungsten (W), and titanium (Ti). Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Although the second redistribution substrate RS2 is illustrated to include three second redistribution dielectric layers RL2, the second redistribution substrate RS2 may include two or at least four second redistribution dielectric layers RL2 each having the second redistribution pattern RP2 therein.

A power may be transmitted through one of the first and second redistribution patterns RP1 and RP2, and a signal may be transmitted through another of the first and second redistribution patterns RP1 and RP2. The first and second redistribution patterns RP1 and RP2 may include power vias and signal vias.

The first semiconductor chip CH1 may be provided relatively closer to and may be electrically connected to the first redistribution substrate RS1, and the second semiconductor chip CH2 may be provided relatively closer to and may be electrically connected to the second redistribution substrate RS2. For example, the first semiconductor chip CH1 may include a first chip pad CP1 adjacent to a bottom surface of the first semiconductor chip CH1 so as to connect to the first redistribution substrate RS1, and the second semiconductor chip CH2 may include a second chip pad CP2 adjacent to a top surface of the second semiconductor chip CH2 so as to connect to the second redistribution substrate RS2. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting,” “in contact with,” or “contact” another element, there are no intervening elements present at the point of contact.

The first semiconductor chip CH1 may be connected to the main semiconductor chip 10 through the first redistribution pattern RP1 of the first redistribution substrate RS1. The first semiconductor chip CH1 may promptly transmit signals through the first redistribution substrate RS1 to the main semiconductor chip 10. The first semiconductor chip CH1 may be a capacitor including silicon (Si). According to aspects of the present inventive concept, as the first semiconductor chip CH1 is formed as a capacitor, it may be possible to effectively remove noise from power signals or input signals and to provide the semiconductor package 1 with increased power integrity.

The mold via 30 may penetrate the first molding layer MD1 to electrically connect the first redistribution substrate RS1 to the second redistribution substrate RS2. The mold via 30 may be disposed on the top surface of the first redistribution substrate RS1 and the bottom surface of the second redistribution substrate RS2. The mold via 30 may be electrically connected to one of uppermost first redistribution patterns RP1 and one of lowermost second redistribution patterns RP2. The mold via 30 may be provided in plural. The mold via 30 may be disposed in the first molding layer MD1. The mold via 30 may be disposed horizontally (e.g., in the first direction) spaced apart from the main semiconductor chip 10 and the semiconductor device 20. When viewed in plan, the mold via 30 may be disposed to surround the main semiconductor chip 10 and the semiconductor device 20. The mold via 30 may be a metal pillar including, for example, copper (Cu).

Among the second redistribution patterns RP2 of the second redistribution substrate RS2, the second redistribution patterns RP2 that connect semiconductor chips to each other may be called a first via structure VS1, and the second redistribution patterns RP2 that connect a semiconductor chip to the mold via 30 may be called a second via structure VS2.

The second semiconductor chip CH2 may be connected through the first via structure VS1 to a fourth semiconductor chip CH4 which will be discussed below, and may be connected to the first redistribution substrate RS1 through the second via structure VS2(1) and the mold via 30. As the second semiconductor chip CH2 is connected through the second via structure VS2(1) to the first redistribution substrate RS1, the second semiconductor chip CH2 may have a longer connection path than that of the first semiconductor chip CH1, and thus may have a relatively slow signal transfer speed. In this case, the second semiconductor chip CH2 may be one of a near field communication (NFC) controller and a touch screen controller chip.

At least one semiconductor device 40 may be disposed on the second redistribution substrate RS2. The at least one semiconductor device 40 may have a top surface located at a lower level than that of the top surface of the main semiconductor chip 10. The second redistribution substrate RS2 may be provided thereon with a second molding layer MD2 that covers the at least one semiconductor device 40 and the lateral surface of the main semiconductor chip 10 so as to expose (i.e., not cover) the top surface of the main semiconductor chip 10. The second molding layer MD2 may have a top surface coplanar with that of the main semiconductor chip 10. As the main semiconductor chip 10 is exposed on the top surface thereof, heat may be easily discharged from the main semiconductor chip 10. The semiconductor package 1 may improve in thermal properties, which may result in prevention of operating delay/error and improvement in reliability. Terms such as “same,” “equal,” “planar,” or “coplanar,” as used herein encompass identicality or near identicality including variations that may occur, for example, due to manufacturing processes. The term “substantially” may be used herein to emphasize this meaning, unless the context or other statements indicate otherwise.

The at least one semiconductor device 40 may include a third semiconductor device 40a and a fourth semiconductor device 40b. The third semiconductor device 40a may include a fourth semiconductor chip CH4, and the fourth semiconductor device 40b may include a fifth semiconductor chip CH5. Each of the fourth semiconductor chip CH4 and the fifth semiconductor chip CH5 may be connected to the second redistribution substrate RS2 through a first conductive pad 41 and a second conductive pad 42, respectively. The first conductive pad 41 may be formed between the fourth semiconductor chip CH4 and the second redistribution substrate RS2, and the second conductive pad 42 may be formed between the fifth semiconductor chip CH5 and the second redistribution substrate RS2. Each of the first conductive pad 41 and the second conductive pad 42 may be connected to a corresponding one of the second redistribution patterns RP2 of the second redistribution substrate RS2. The first conductive pad 41 and the second conductive pad 42 may include a conductive material, for example, copper (Cu).

The third to fifth semiconductor chips CH3 to CH5 may be one selected from a microelectromechanical system (MEMS) device chip and a memory device chip such as a flash memory chip, a dynamic random access memory (DRAM) chip, a static random access memory (SRAM) chip, an electrically erasable programmable read-only memory (EEPROM) chip, a phase change random access memory (PRAM) chip, a magnetic random access memory (MRAM) chip, a resistive random access memory (ReRAM) chip, a high bandwidth memory (HBM) chip, and a hybrid memory cubic (HMC) chip.

The fourth semiconductor chip CH4 and the fifth semiconductor chip CH5 may be connected to the first via structure VS1 or the second via structure VS2 of the second redistribution substrate RS2. The fourth semiconductor chip CH4 may be positioned on the first semiconductor device 21, and the fifth semiconductor chip CH5 may be positioned on the second semiconductor device 22. At least a portion of the fourth semiconductor chip CH4 may vertically overlap at least portions of the first and second semiconductor chips CH1 and CH2, and at least a portion of the fifth semiconductor chip CH5 may vertically overlap at least a portion of the third semiconductor chip CH3.

The fourth semiconductor chip CH4 may be connected either to the second semiconductor chip CH2 through the first via structure VS1 or to the first redistribution substrate RS1 through the mold via 30 and the second via structure VS2(2) of the second redistribution substrate RS2.

The fifth semiconductor chip CH5 may be connected to the first redistribution substrate RS1 through the mold via 30 and the second via structure VS2(3) of the second redistribution substrate RS2.

The fourth and fifth semiconductor chips CH4 and CH5 may each be provided in plural, and the number of the fourth and fifth semiconductor chips CH4 and CH5 may be variously changed without being limited to that shown.

In the present embodiment of the semiconductor package 1, as at least two of the semiconductor chips are provided in the form of vertical overlap or stack arrangement, the semiconductor package 1 may have an increased degree of freedom of design and may eventually become small in size.

The second molding layer MD2 may be provided on the second redistribution substrate RS2. The second molding layer MD2 may cover the top surface of the second redistribution substrate RS2, the lateral surface of the main semiconductor chip 10, and lateral and top surfaces of each of the fourth and fifth semiconductor chips CH4 and CH5.

The top surface of each of the fourth and fifth semiconductor chips CH4 and CH5 may be located at a lower level than that of the top surface of the main semiconductor chip 10, and thus the second molding layer MD2 may expose (i.e., not cover) the top surface of the main semiconductor chip 10 while completely covering the fourth semiconductor chip CH4 and the fifth semiconductor chip CH5. For example, the top surface of the second molding layer MD2 may be located at a level substantially the same as that of the top surface of the main semiconductor chip 10. The second molding layer MD2 may include a dielectric polymer, such as an epoxy molding compound (EMC).

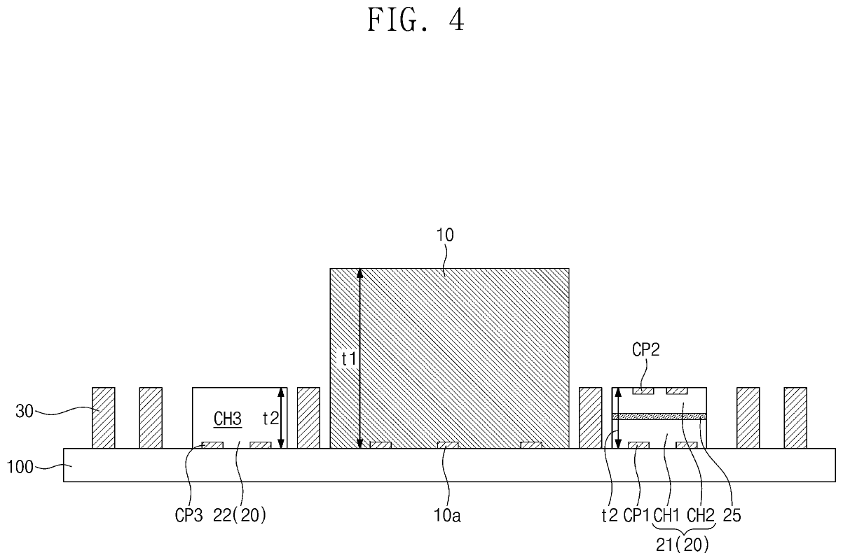

FIGS. 4 to 15 illustrate cross-sectional views showing a method of fabricating a semiconductor package according to some embodiments of the present inventive concepts.

Referring to FIG. 4, a main semiconductor chip 10 and at least one semiconductor device 20 may be disposed on a carrier substrate 100. The carrier substrate 100 may include a polymer. For example, the carrier substrate 100 may include a glue tape, and thus, the main semiconductor chip 10 and the at least one semiconductor device 20 may be attached to the carrier substrate 100.

The main semiconductor chip 10 may include main chip pads 10a adjacent to a bottom surface of the main semiconductor chip 10.

The at least one semiconductor device 20 may include a first semiconductor device 20 (hereinafter designated by reference numeral 21) and a second semiconductor device 20 (hereinafter designated by reference numeral 22). The first semiconductor device 21 and the second semiconductor device 22 may be disposed spaced apart from each other and on opposite sides of the main semiconductor chip 10. Alternatively, the first semiconductor device 21 and the second semiconductor device 22 may be disposed side by side on one side of the main semiconductor chip 10.

In this case, the first semiconductor device 21 may include a first semiconductor chip CH1 and a second semiconductor chip CH2. The first semiconductor chip CH1 may be attached to the carrier substrate 100, and then the second semiconductor chip CH2 may be stacked on the first semiconductor chip CH1. When the first semiconductor chip CH1 is attached to the carrier substrate 100, an adhesion layer 25 may be formed on a top surface of the first semiconductor chip CH1 and the second semiconductor chip CH2 may be attached to the adhesion layer 25. The first semiconductor chip CH1 may include a first chip pad CP1 adjacent to a bottom surface of the first semiconductor chip CH1, and the second semiconductor chip CH2 may include a second chip pad CP2 adjacent to a top surface of the second semiconductor chip CH2.

The second semiconductor device 22 may include a third semiconductor chip CH3, and the third semiconductor chip CH3 may include a third chip pad CP3 adjacent to a bottom surface of the third semiconductor chip CH3.

A mold via 30 may be disposed on the carrier substrate 100. The mold via 30 may be provided in plural, and the plurality of mold vias 30 may be disposed on opposite sides of each of the first semiconductor device 21 and the second semiconductor device 22. Each of the mold vias 30 may have a pillar shape. The mold via 30 is not limited to the shape mentioned above, and may be designed to have various shapes.

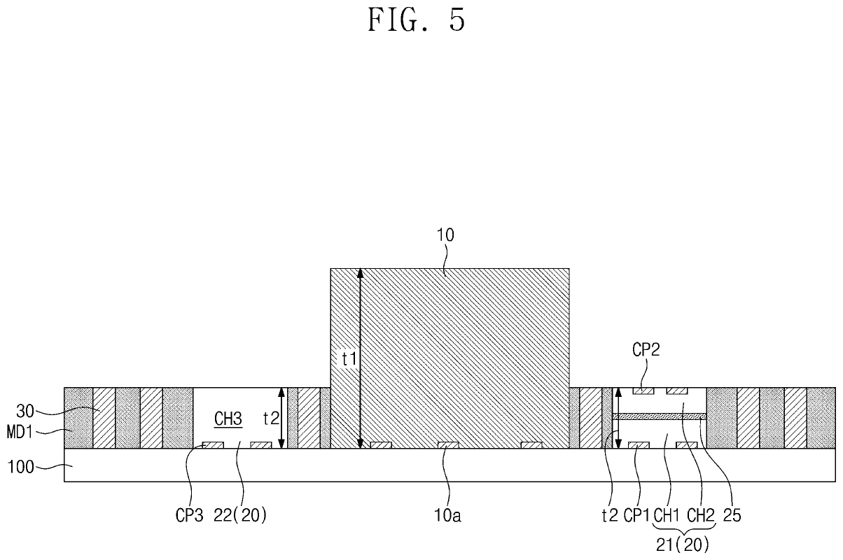

Referring to FIG. 5, a first molding layer MD1 may be formed on the carrier substrate 100. The molding layer MD1 may cover the main semiconductor chip 10, the semiconductor device 20, and a top surface of the carrier substrate 100. The first molding layer MD1 may be formed to have a thickness to expose a top surface of the semiconductor device 20. In this case, because the top surface of the main semiconductor chip 10 is located at a higher level than that of the top surface of the semiconductor device 20, the first molding layer MD1 may cover a portion of a lateral surface of the main semiconductor chip 10 and may expose another portion of the lateral surface and a top surface of the main semiconductor chip 10.

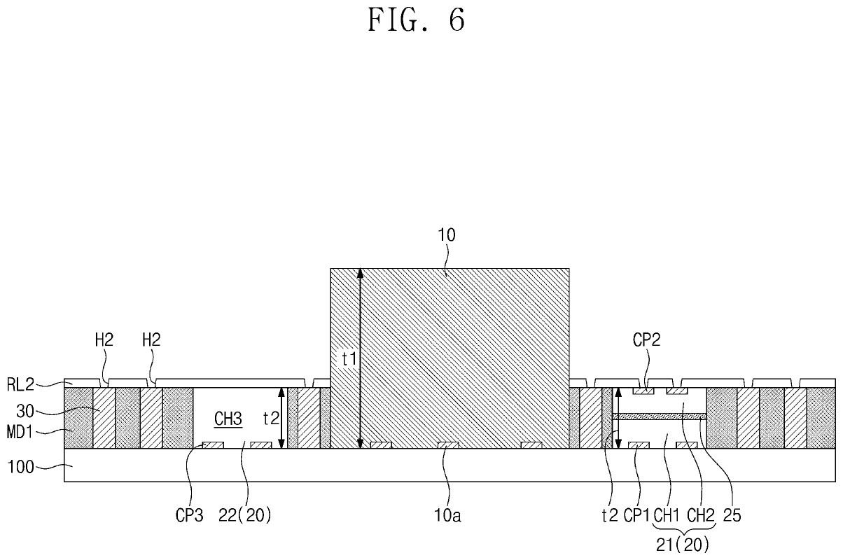

Referring to FIG. 6, a second redistribution dielectric layer RL2 may be formed on the top surface of the second semiconductor chip CH2 and a top surface of the third semiconductor chip CH3. The second redistribution dielectric layer RL2 may cover the top surface of the second semiconductor chip CH2 and the top surface of the third semiconductor chip CH3. The second semiconductor chip CH2 may include second chip pads CP2 adjacent to the top surface of the second semiconductor chip CH2.

The second redistribution dielectric layer RL2 may be patterned to form a plurality of second holes H2 in the second redistribution dielectric layer RL2. The second holes H2 may expose top surfaces of the second chip pads CP2 and top surfaces of the mold vias 30. The second redistribution dielectric layer RL2 may be patterned by exposure and development processes. For example, the second holes H2 may have tapered sidewalls.

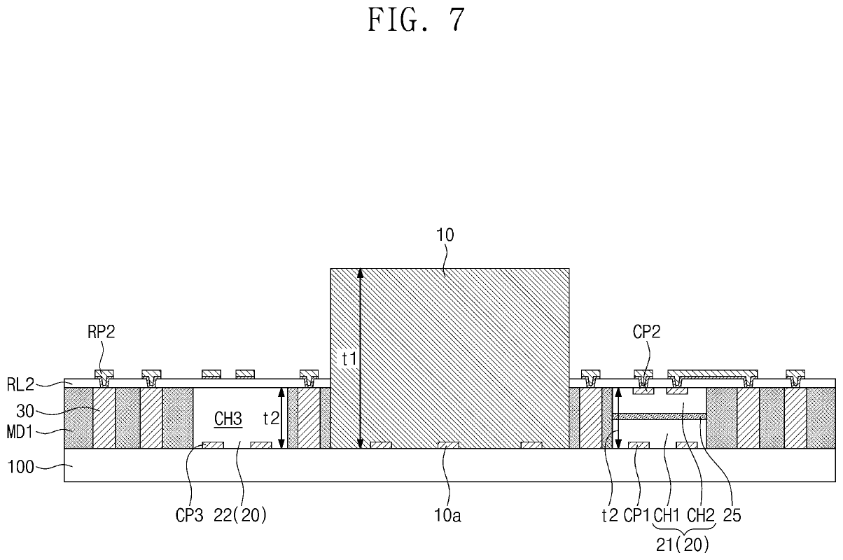

Referring to FIG. 7, second redistribution patterns RP2 may be formed on the second redistribution dielectric layer RL2. For example, the formation of the second redistribution pattern RP2 may include forming a seed layer on the second redistribution dielectric layer RL2, forming a conductive layer by performing an electroplating process in which the seed layer is used as an electrode, and patterning the conductive layer and the seed layer. The conductive layer may include metal, such as copper (Cu). The second redistribution pattern RP2 may include a second line part L2 provided in the second hole H2 and a second via part V2 provided on the second redistribution dielectric layer RL2.

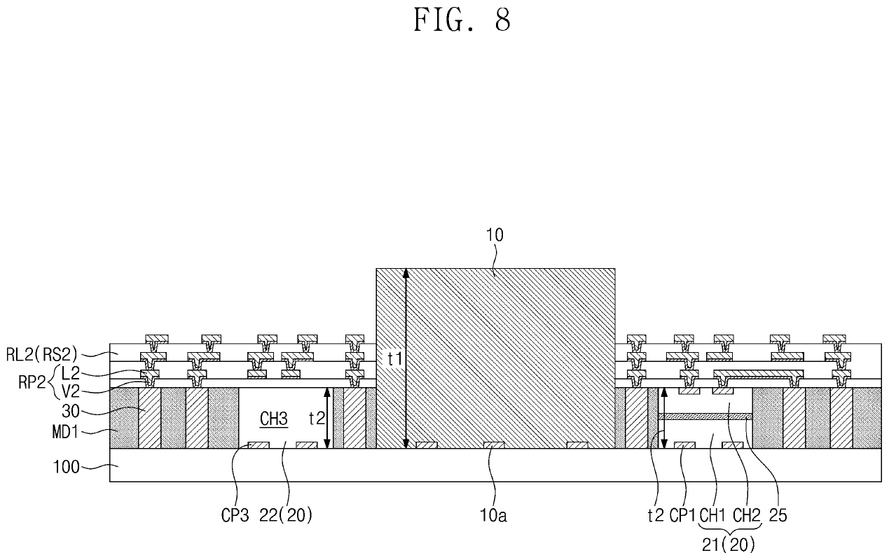

Referring to FIG. 8, the formation of the second redistribution dielectric layer RL2 and the second redistribution patterns RP2 may be repeatedly performed. Therefore, a second redistribution substrate RS2 may be formed which includes a plurality of stacked second redistribution dielectric layers RL2 and a plurality of stacked second redistribution patterns RP2.

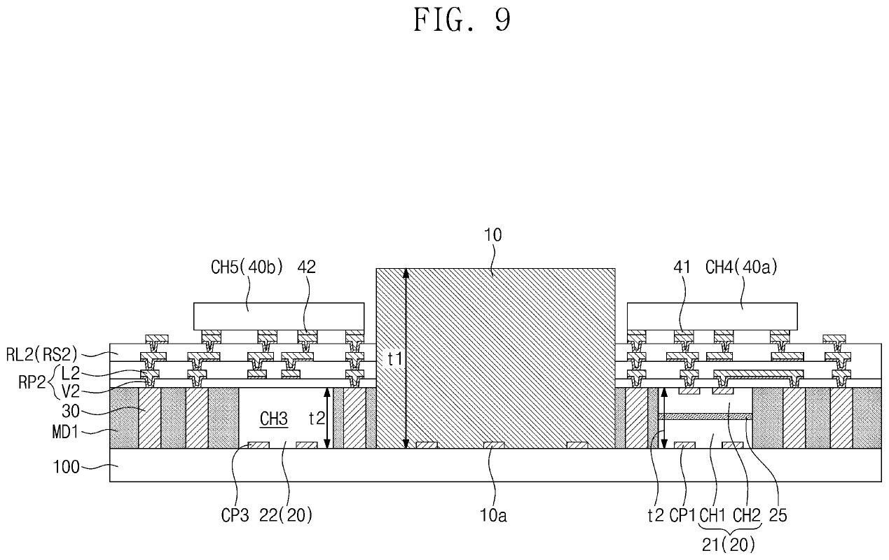

Referring to FIG. 9, a third semiconductor device 40a and a fourth semiconductor device 40b may be disposed on the second redistribution substrate RS2. On the second redistribution substrate RS2, a fourth semiconductor chip CH4 may be disposed to vertically overlap the second semiconductor chip CH2 and a fifth semiconductor chip CH5 may be disposed to vertically overlap the third semiconductor chip CH3. The fourth semiconductor chip CH4 may be connected through a first conductive pad 41 to the second redistribution substrate RS2, and the fifth semiconductor chip CH5 may be connected through a second conductive pad 42 to the second redistribution substrate RS2. The first conductive pad 41 may be formed to correspond to the first redistribution pattern RP1 of the first redistribution substrate RS1, and the second conductive pad 42 may be formed to correspond to the second redistribution pattern RP2 of the second redistribution substrate RS2.

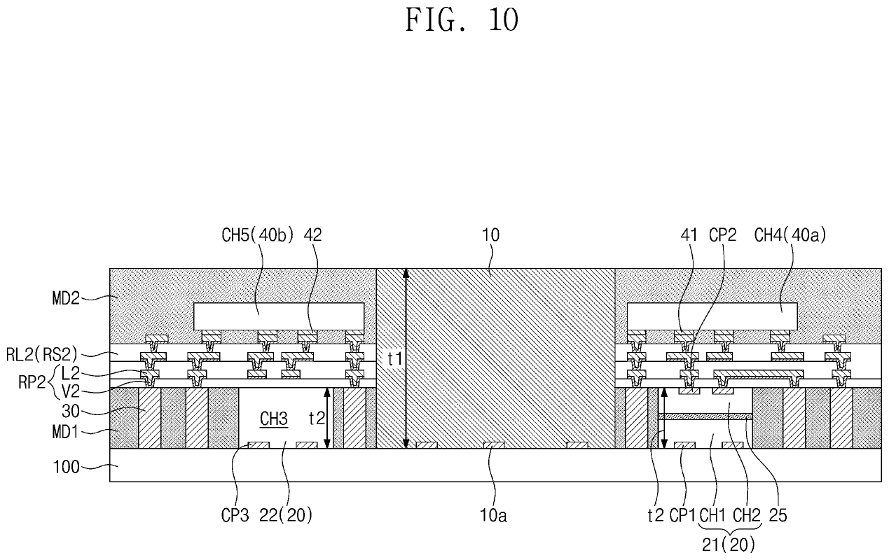

Referring to FIG. 10, a second molding layer MD2 may be formed to cover the fourth semiconductor chip CH4, the fifth semiconductor chip CH5, and the second redistribution substrate RS2. The main semiconductor chip 10 may have, at its lateral surface, a portion that is not molded by the first molding layer MD1, and the second molding layer MD2 may mold the non-molded portion at the lateral surface of the main semiconductor chip 10 while exposing the top surface of the main semiconductor chip 10. In this case, because a top surface of each of the fourth and fifth semiconductor chips CH4 and CH5 is located at a lower level than that of the top surface of the main semiconductor chip 10, the second molding layer MD2 may completely cover the fourth semiconductor chip CH4 and the fifth semiconductor chip CH5.

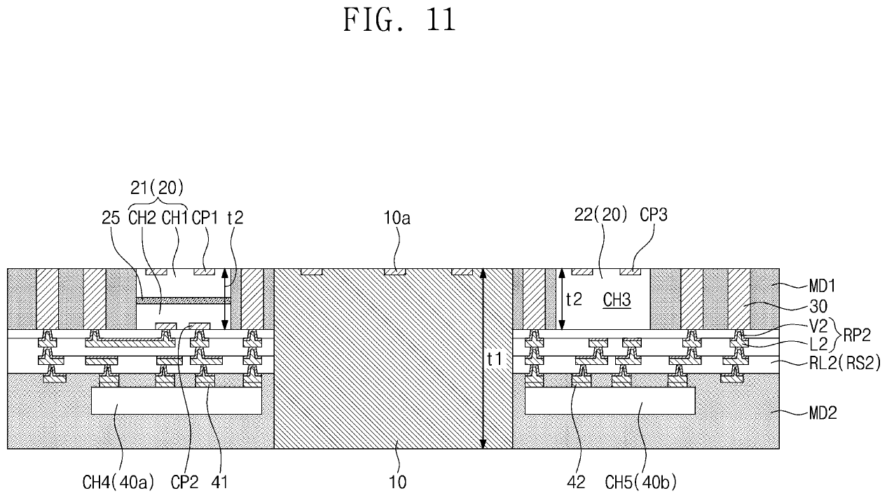

Referring to FIG. 11, the carrier substrate 100 may be turned upside down to allow the bottom surface of the main semiconductor chip 10 to face upwardly, and the carrier substrate 100 may be removed.

For uniformity of description, the languages of a top surface, a bottom surface, an upper portion, and a lower portion will be described based on FIG. 2.

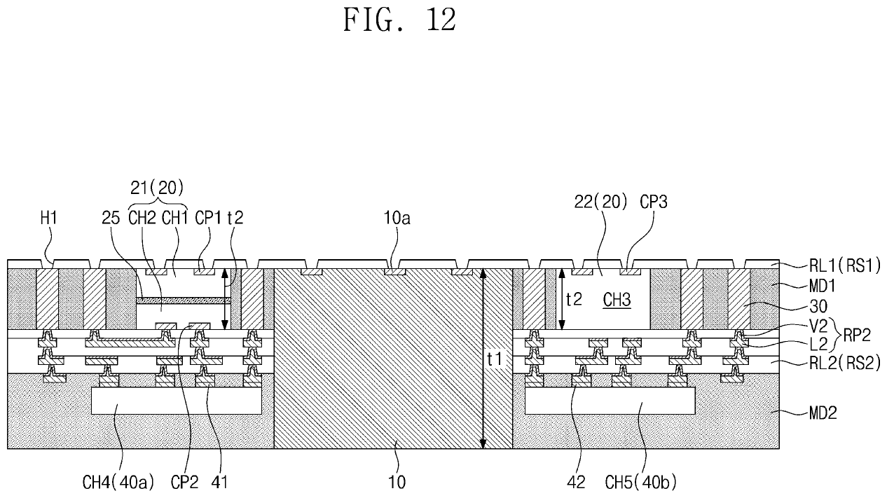

The removal of the carrier substrate 100 may expose the main chip pads adjacent to the bottom surface of the main semiconductor chip 10, the first chip pads CP1 adjacent to the bottom surface of the first semiconductor chip CHL and the third chip pads CP3 adjacent to the bottom surface of the third semiconductor chip CH3. Referring to FIG. 12, a first redistribution dielectric layer RL1 may be formed on the bottom surface of the main semiconductor chip 10, a bottom surface of the semiconductor device 20, and bottom surfaces of the mold vias 30. The first redistribution dielectric layer RL1 may cover the bottom surface of the main semiconductor chip 10, the bottom surface of the semiconductor device 20, and the bottom surfaces of the mold vias 30.

The first redistribution dielectric layer RL1 may be patterned to form a plurality of first holes H1 in the first redistribution dielectric layer RL1. The first holes H1 may expose the first chip pads CP1, the third chip pads CP3, and the bottom surfaces of the mold vias 30. The first redistribution dielectric layer RL1 may be patterned by exposure and development processes. For example, the first holes H1 may have tapered sidewalls.

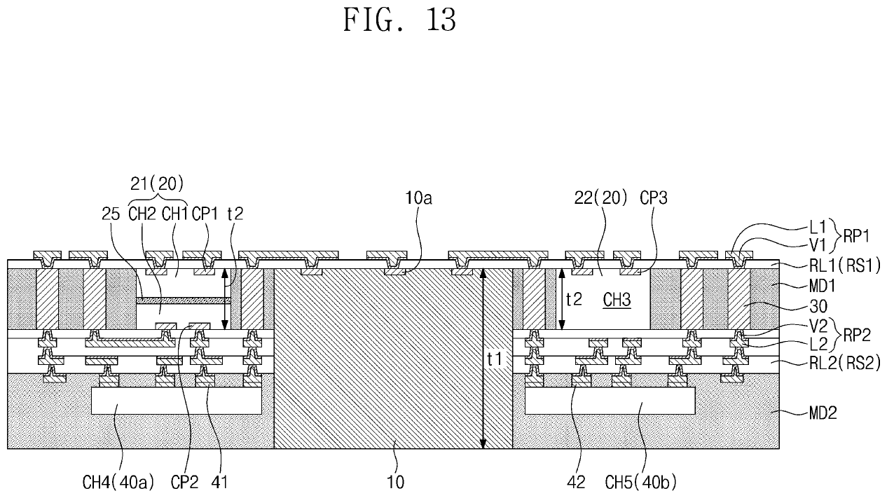

Referring to FIG. 13, first redistribution patterns RP1 may be formed on the first redistribution dielectric layer RL1. For example, the formation of the first redistribution pattern RP1 may include forming a seed layer on the first redistribution dielectric layer RL1, forming a conductive layer by performing an electroplating process in which the seed layer is used as an electrode, and patterning the seed layer and the conductive layer. The conductive layer may include metal, such as copper (Cu). The first redistribution pattern RP1 may include a first line part L1 provided in the first hole H1 and a first via part V1 provided on the first redistribution dielectric layer RL1.

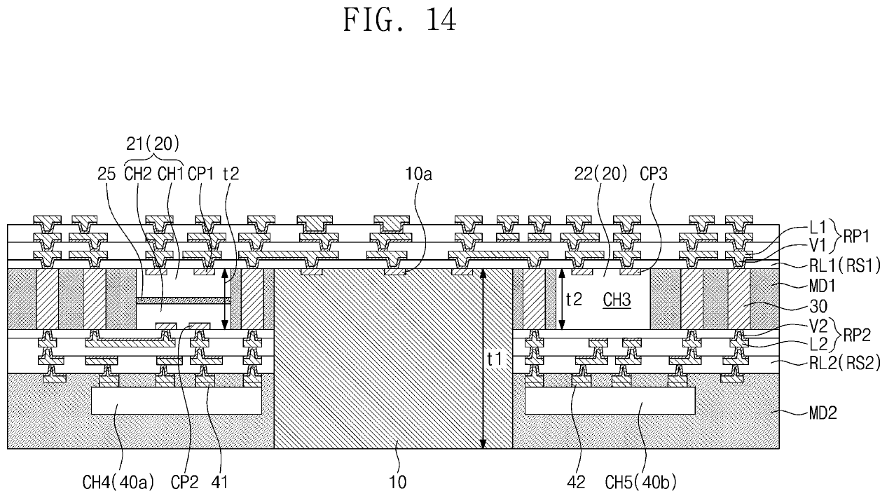

Referring to FIG. 14, the formation of the first redistribution dielectric layer RL1 and the first redistribution patterns RP1 may be repeatedly performed. Therefore, a first redistribution substrate RS1 may be formed which includes a plurality of stacked first redistribution dielectric layers RL1 and a plurality of stacked first redistribution patterns RP1.

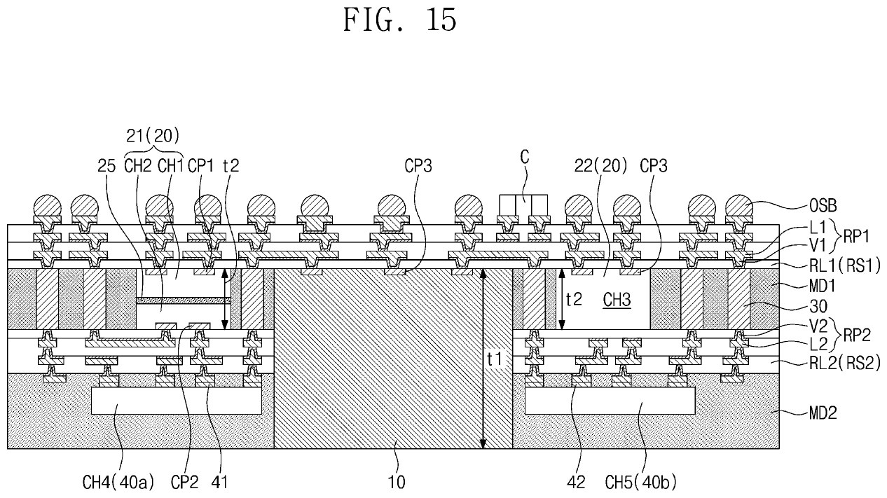

Referring to FIG. 15, a plurality of external connection terminals OSB may be formed on bottom surfaces of lowermost ones of the first redistribution patterns RP1. The external connection terminals OSB may be formed to correspond to and to electrically connect to the lowermost first redistribution patterns RP1. The external connection terminals OSB may be used to allow signal communication between an external apparatus and the main semiconductor chip 10 and the first, second, third, fourth, and fifth semiconductor chips CH1, CH2, CH3, CH4, and CH5. A sub-semiconductor package may be defined to indicate a semiconductor structure with which the external connection terminals OSB are combined as discussed above.

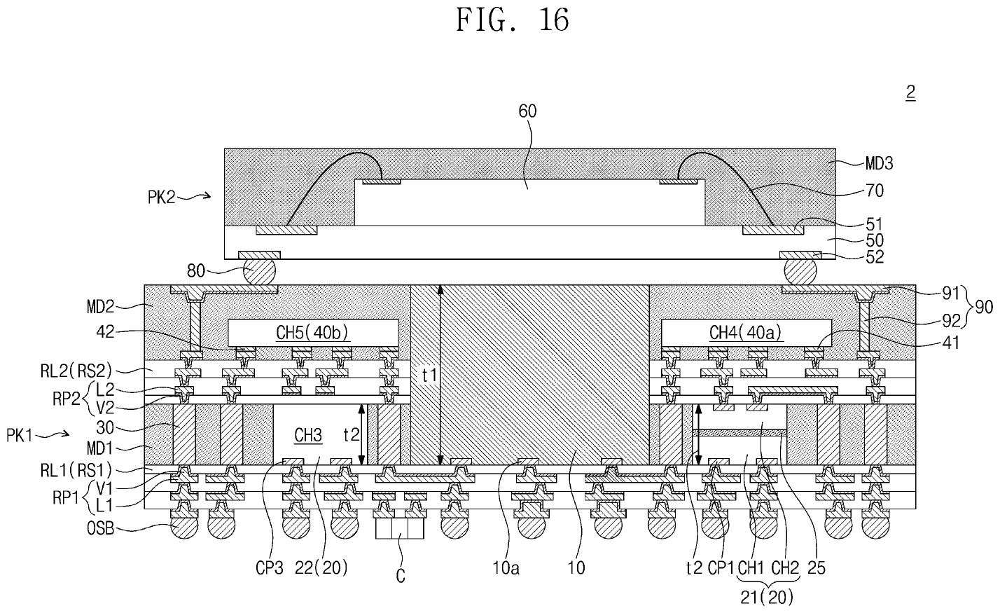

FIG. 16 illustrates a cross-sectional view showing a semiconductor package according to some embodiments of the present inventive concepts.

Referring to FIG. 16, a semiconductor package 2 according to the present embodiment may include a first sub-semiconductor package PK1 and a second sub-semiconductor package PK2 stacked on the first sub-semiconductor package PK1. The first sub-semiconductor package PK1 may have the same structure as that of the sub-semiconductor package discussed with reference to FIGS. 1 to 15. The second sub-semiconductor package PK2 may include a package substrate 50, a semiconductor device 60 mounted on the package substrate 50, and a third molding layer MD3 that covers the semiconductor device 60.

The semiconductor device 60 may be electrically connected to the package substrate 50 through, for example, one or more wires 70. The semiconductor device 60 may be a single semiconductor die or chip, or may be a semiconductor package including a plurality of semiconductor dies of the same type or different types. The semiconductor device 60 may be one selected from an image sensor chip such as CMOS image sensor (CIS), a microelectromechanical system (MEMS) device chip, an application specific integrated circuit (ASIC) chip, and a memory device chip such as a flash memory chip, a dynamic random access memory (DRAM) chip, a static random access memory (SRAM) chip, an electrically erasable programmable read-only memory (EEPROM) chip, a phase change random access memory (PRAM) chip, a magnetic random access memory (MRAM) chip, a resistive random access memory (ReRAM) chip, a high bandwidth memory (HBM) chip, and a hybrid memory cubic (HMC) chip.

The third molding layer MD3 may include the same material as that of the first molding layer MD1 and the second molding layer MD2.

The wire 70 may include copper or gold.

The package substrate 50 may be, for example, a bi-layered or multi-layered printed circuit board. The package substrate 50 may include an upper conductive pattern 51 disposed on a top surface thereof and a lower conductive pattern 52 disposed on a bottom surface thereof. The package substrate 50 may be provided therein with an internal line (not shown) that connects the upper conductive pattern 51 and the lower conductive pattern 52 to each other. The upper conductive pattern 51 and the lower conductive pattern 52 may include at least one selected from gold, copper, aluminum, and nickel.

The first sub-semiconductor package PK1 and the second sub-semiconductor package PK2 may be connected through a connection member 80. The connection member 80 may connect the lower conductive pattern 52 to a connection structure 90 provided in the second molding layer MD2. The connection structure 90 may be exposed on a top surface of the second molding layer MD2 to come into contact with the connection member 80.

A top end of the connection structure 90 may be in contact with the connection member 80, and a bottom end of the connection structure 90 may be connected to the second redistribution pattern RP2. The connection structure 90 may include a pattern part 91 and a post part 92 that extends in a downward direction from the pattern part 91. The pattern part 91 may be in contact with the connection member and the post part 92 may be connected to the second redistribution pattern RP2.

The connection member 80 may include at least one selected from solder balls, conductive bumps, and conductive pillars. The connection member 80 may be formed of at least one selected from tin, lead, silver, copper, nickel, and gold.

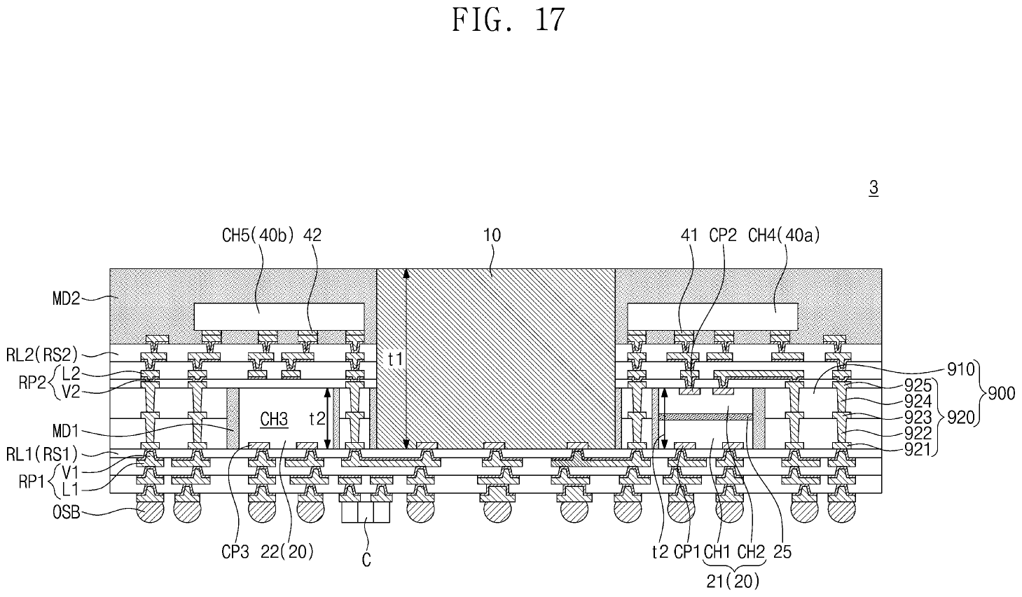

FIG. 17 illustrates a cross-sectional view showing a semiconductor package according to some embodiments of the present inventive concepts.

Referring to FIG. 17, a semiconductor package 3 may be shaped like a chip-first type fan-out panel level package (FOPLP). The semiconductor package 3 may include a first redistribution substrate RS1, a connection substrate 900 mounted on the first redistribution substrate RS1, and a main semiconductor chip 10.

The connection substrate 900 may be disposed on a side of the main semiconductor chip 10. The connection substrate 900 may include a plurality of base layers 910 and a conductive structure 920. The base layers 910 may include a dielectric material. For example, the base layers 910 may include a carbon-based material, a ceramic, or a polymer. The conductive structure 920 may include a connection pad 921, a first connection via 922, a first connection line 923, a second connection via 924, and a second connection line 925. The connection lines 923 and 925 may each have a pad shape or a linear shape. When viewed in plan, an arrangement of the conductive structure 920 may be identical or similar to that of the mold vias 30 depicted in FIG. 2. The connection substrate 900 may be connected through the first redistribution pattern RP1 to the first redistribution substrate RS1.

Other configurations may be identical or similar either to those of the semiconductor package 1 discussed with reference to FIGS. 1 to 15, or to those of the semiconductor package 2 discussed with reference to FIG. 16.

According to aspects of the present inventive concept, as an application processor (AP) main semiconductor chip is placed which has a relatively increased thickness, a semiconductor package may improve in thermal properties.

Moreover, as the main semiconductor chip is exposed on a top surface thereof, heat may be easily discharged from the main semiconductor chip, and therefore the semiconductor package may improve in thermal properties, which may result in prevention of operating delay/error and improvement in reliability of the semiconductor package.

Furthermore, semiconductor chips may be stacked to partially overlap each other to reduce a size of the semiconductor package and to exhibit high capacity and excellent performance.

According to aspects of the present inventive concept, as a capacitor chip is disposed, it may be possible to effectively remove noise from power signals or input signals and to provide the semiconductor package with increased power integrity.

Although aspects of the present inventive concept have been described in connection with exemplary embodiments illustrated in the accompanying drawings, it will be understood by one of ordinary skill in the art that variations in form and detail may be made therein without departing from the spirit and essential feature of aspects of the present inventive concept. The above disclosed embodiments should thus be considered illustrative and not restrictive.

What is claimed is:

1. A semiconductor package, comprising:
a main semiconductor chip having a first thickness;
at least one semiconductor device on one side of the main semiconductor chip and having a second thickness less than the first thickness;
a first molding layer that covers the main semiconductor chip and the semiconductor device so as to expose a top surface of the semiconductor device and to expose a top surface and a portion of a lateral surface of the main semiconductor chip;
a first redistribution substrate below the first molding layer;
a second redistribution substrate on the first molding layer; and
a mold via that penetrates the first molding layer and connects the first redistribution substrate to the second redistribution substrate.

2. The semiconductor package of claim 1, wherein the at least one semiconductor device includes a first semiconductor device and a second semiconductor device that are on opposite sides of the main semiconductor chip,
wherein each of the first semiconductor device and the second semiconductor device includes at least one semiconductor chip.

3. The semiconductor package of claim 2, wherein at least one of the first semiconductor device and the second semiconductor device includes:
a first semiconductor chip connected to the first redistribution substrate; and
a second semiconductor chip on the first semiconductor chip and connected to the second redistribution substrate.

4. The semiconductor package of claim 3, wherein the first semiconductor chip is a capacitor including silicon (Si).

5. The semiconductor package of claim 3, wherein the first redistribution substrate includes a first redistribution dielectric layer and first redistribution patterns in the first redistribution dielectric layer,
wherein each of the first redistribution patterns includes a first line part and a first via part on the first line part.

6. The semiconductor package of claim 3, wherein the second redistribution substrate includes a second redistribution dielectric layer and a second redistribution pattern in the second redistribution dielectric layer,
wherein the second redistribution pattern includes a second line part and a second via part below the second line part.

7. The semiconductor package of claim 6, further comprising a third semiconductor device on the second redistribution pattern,
wherein the second redistribution pattern comprises via structures,
wherein the via structures include:
a first via structure that connects the third semiconductor device and the second semiconductor chip to each other; and
a second via structure that connects the second semiconductor chip and the mold via to each other.

8. The semiconductor package of claim 7, wherein the second semiconductor chip is connected through the second via structure to the first redistribution substrate and is one of a near field communication (NFC) controller and a touch screen controller chip.

9. The semiconductor package of claim 7, further comprising a second molding layer that covers the third semiconductor device and exposes the top surface of the main semiconductor chip,
wherein a top surface of the third semiconductor chip is at a level lower than a level of the top surface of the main semiconductor chip.

10. The semiconductor package of claim 9, wherein a top surface of the second molding layer is coplanar with the top surface of the main semiconductor chip.

11. The semiconductor package of claim 7, further comprising a fourth semiconductor device on the second redistribution pattern and spaced apart from the third semiconductor device and on an opposite side of the main semiconductor chip.

12. A semiconductor package, comprising:
a first redistribution substrate;
a main semiconductor chip on the first redistribution substrate;
a second redistribution substrate on the first redistribution substrate, a top surface of the second redistribution substrate being at a level lower than a level of the main semiconductor chip;
a first molding layer between the first redistribution substrate and the second redistribution substrate; and
a second molding layer that covers the second redistribution substrate and exposes a top surface of the main semiconductor chip.

13. The semiconductor package of claim 12, further comprising a semiconductor device between the first redistribution substrate and the second redistribution substrate, the semiconductor device being horizontally spaced apart from the main semiconductor chip,
wherein the semiconductor device includes a plurality of stacked semiconductor chips.

14. The semiconductor package of claim 13, wherein the plurality of semiconductor chips include a first semiconductor chip and a second semiconductor chips that are different types from each other.

15. The semiconductor package of claim 14, wherein
the first semiconductor chip is a capacitor including silicon (Si), and
the second semiconductor chip is one of a near field communication (NFC) controller and a touch screen controller chip.

16. The semiconductor package of claim 14, wherein
the first semiconductor chip includes first chip pads adjacent to a bottom surface of the first semiconductor chip,
the second semiconductor chip includes second chip pads adjacent to a top surface of the second semiconductor chip,
the first redistribution substrate includes first redistribution patterns that contact the first chip pads, and
the second redistribution substrate includes second redistribution patterns that contact the second chip pads.

17. A semiconductor package, comprising:
a main semiconductor chip;
a first redistribution substrate below the main semiconductor chip;
external connection terminals bonded to a bottom surface of the first redistribution substrate;
first redistribution patterns in the first redistribution substrate;
a second redistribution substrate that extends parallel to the first redistribution substrate and extends in an outward direction from a lateral surface of the main semiconductor chip;
second redistribution patterns in the second redistribution substrate;
at least one semiconductor device between the first redistribution substrate and the second redistribution substrate;
a first molding layer between the first redistribution substrate and the second redistribution substrate, the first molding layer covering a portion of the lateral surface of the main semiconductor chip; and
a second molding layer that covers the second redistribution substrate and another portion of the lateral surface of the main semiconductor chip, the second molding layer exposing a top surface of the main semiconductor chip,
wherein each of the first redistribution patterns includes a first line part and a first via part on the first line part,
wherein each of the second redistribution patterns includes a second line part and a second via part on the second line part,
wherein one of the first and second redistribution patterns transmits a power,
wherein another of the first and second redistribution patterns transmits a signal,
wherein the main semiconductor chip has a first thickness,
wherein the at least one semiconductor device has a second thickness, and
wherein the first thickness is about 2 to 5 times the second thickness.

18. The semiconductor package of claim 17, wherein a top surface of the second molding layer is coplanar with the top surface of the main semiconductor chip.

19. The semiconductor package of claim 17, wherein the second thickness is the same as a distance between the first redistribution substrate and the second redistribution substrate.

20. The semiconductor package of claim 17, wherein the at least one semiconductor device includes a plurality of stacked semiconductor chips.
